(19) United States
(12) Patent Application Publication
(10) Pub. No.: US 2012/0199792 A1
(43) Pub. Date: Aug. 9, 2012

(54) Novel Cherkasky's synthetic diamonds and diamond-like materials and methods and devices for production thereof

(76) Inventor: Alexander Cherkasky, Duesseldorf (DE)

(21) Appl. No.: 13/385,079

(22) Filed: Feb. 1, 2012

(30) Foreign Application Priority Data
Feb. 4, 2011 (DE) DE 102011010422.4

(51) Int. Cl. C30B 29/10; B01J 19/00; C09K 11/08

(52) U.S. Cl. 252/301.4 R; 501/86; 422/165

(57) ABSTRACT

The object of the invention is to increase the yield of the HPHT—(High-Pressure High-Temperature)—Technology for production of synthetic diamonds and diamond-like materials as well as to achieve the continuous production of large amounts or quantities of synthetic diamonds with perfect or high quality.

The object of the invention will be reached by methods and devices according to the present invention, wherein the method comprises the following steps: cultivation or collection of biomass, preparing and chemical modification of biomass preferably by (adding or enriching with) salt or salts containing at least one catalyst, incineration of biomass to ash, adding to ash modifiers including salt or salts containing at least one catalyst, HPHT-treatment of the resulting carbon-containing matrix and the isolation of the products after the HPHT-treatment.

### FIELD OF THE INVENTION

The present invention relates to the material science and the field of synthetic diamonds and diamond-like materials and methods and devices for production thereof.

### BACKGROUND OF THE INVENTION

Diamond is a modification of carbon, the basic element of the organic matter.

Both natural and synthetic diamonds are used as jewels as well as for technical purposes for hardening instruments and devices for drilling, milling and polishing of metals, glass, plastics and concrete. Other new uses include superhard material-based machines and devices for number of uses, the uses in electronics, heat conductors, semiconductors, i.e. preferably for computers and mobile communication devices as well as for organic chemistry as electrodes for redox reactions, for research of DNA-DNA-interactions as well as for uses as detal materials, especially dental implantates and fillings.

Natural diamond deposits will be exhausted and they cannot provide enough diamonds especially for technical uses, whereby the demand for diamonds grows.

Known are different methods for synthesis, an industrial production or synthetic diamonds and diamond-like materials. These methods include HPHT (High-Pressure High-Temperature)—Technology, CVD (chemical vapor deposition), ultrasound synthesis and shock waves synthesis by controlled explosions for creating extremely high pressures, for very short times. The HPHT-Technology is used to convert carbon, preferably as ash or graphite to the diamond modification of carbon. HPHT is used for current production of synthetic diamonds and diamond-like materials, but all the methods listed above have limitations both in quantity and in quality of synthetic diamonds.

Related prior art i.e. known technologies relating to the description of HPHT- and CVD-technologies include the following publications: U.S. Pat. No. 3,652,220 (Lindstrom C. et al, “Method of manufacturing synthetic diamonds”), GB1300316 (“Synthetic diamond production”), EP2189555 (Linares R. C. et al “Method for producing synthetic diamond by CVD”), WO2007002402 (Chodelka, R. et al “An apparatus and method for growing a synthetic diamond”) as well as publications of R. E. Page JR and J. Hatleberg relating to synthetic of diamonds from dead humans, animals or plants US20040154528(Page, JR. R. E. “Method for making synthetic gems comprising elements recovered from humans or animals and the product thereof”) and patent applications of J. Hatleberg US20040071623 and US20090202421 (“Synthetic diamonds prepared from roses”) and US20100178233 (“Synthetic diamonds prepared from organic materials”).

The contents disclosed in the publications of J. Hatleberg and R. E. Page JR are not novel because of the disclosure in the patent U.S. pat. No. 3,652,220, wherein a “carbonaceous material” is disclosed. This concerns also the patent application US20080145299 (Parrondo, M. R. et al “Personalized synthetic diamond of different colours, obtained from (living or dead) human or animal keratin and production method thereof”).

Current synthetic diamonds have or show high metal concentrations and therefore they can be distinguished from natural diamonds, preferably by known spectroscopic methods. High concentrations of catalyst metals including iron, nickel, cobalt, aluminium are resulted from the conditions of reactions during the HPHT-process by which pure carbon in form of graphite will be solved or mixed with a metal catalyst. It means that carbon will be, at first, purified from metal(s) and than will be mixed with metal(s), whereby natural diamonds contain(ed) metal(s) during their original, initial, natural synthesis process.

The conditions for the HPHT-synthesis comprise pressures in range of 5-10 GPa (Gigapascal, 50.000-100.000 bar), temperatures in range of 1.500° C.-3.500° C. and time ranges of 10 hours to 3 weeks.

Preferred conditions comprise the pressures in ranges of 5-6 GPa, temperatures in ranges of 1.500° C.-2.500° C. and 2 weeks. The quantity and quality of products depends on the material composition of or in carbon matrix or C-Matrix. If this C-Matrix contains big metal inclusions, the resulting synthetic diamond products will be dark and not qualitative.

Natural eclogitic diamonds arise from detritus, i.e. from carbon of organic origin. This organic matter contains metals, also in form of salts, whereby these metals act as catalysts. Thus, natural diamonds are synthesized from natural organic carbon matrix. Therefore, it is also not necessary to purify carbon and than mix it with metals in order to produce synthetic diamonds.

### SUMMARY OF THE INVENTION

The present invention relates to the material science and the field of synthetic diamonds and diamond-like materials and methods and devices for production thereof

The object of the invention is to increase the yield of the HPHT—(High-Pressure High-Temperature)—Technology for production of synthetic diamonds and diamond-like materials as well as to achieve the continuous production of large amounts or quantities of synthetic diamonds with perfect or high quality.

The object of the invention will be reached by methods and devices according to the present invention, wherein the method comprises the following steps: cultivation or collection of biomass, preparing and chemical modification of biomass preferably by salt or salts containing at least one catalyst, incineration of biomass to ash, adding to ash modifiers including salt or salts containing at least on catalyst, HPHT-treatment of the resulting carbon-containing matrix and the isolation of the products after the HPHT-treatment.

The device according to the present invention carries out the steps of the method according to the present invention.

The steps may include also

a. adding to the biomass substances for drying this biomass, wherein these drying substances comprise the following substances, but are not limited to them: calcium chloride, sulphuric acid, silica gel, phosphorus pentoxide metal oxides, compounds comprising iron, calcium, or their combinations,

b. powdering, powderization or pounding the dryed biomass,

c. adding fuel for incineration wherein the fuel substance includes the following substances, but is not limited to them: kerosene, benzene or gasoline or petrol, coke, coal, charcoal, anthracite or their combinations,

d. adding carbonaceous or carbon-rich material comprising the following substances, but is not limited to them: graphite, an ash, glass carbon, amorphous carbon, carbon nanotubes, fullerene or other form of carbon or their combinations,

e. adding at least one non-metal including phosphorus (P), sulphur (S), boron (B), telluric (Te), selenium (Se), silicium (Si), arsenic (As), antimony (Sb) or their compounds or their combinations.

The device for carrying out the method according to the present invention comprises:

a. at least one HPHT-apparatus comprising both heater, preferably a graphite heater, and press, preferably hydraulic or oil press, with at least one chamber or capsule for carbon-containing matrix,

b. at least one incinerator,

c. chambers, reactors, bioreactor(s), containers, for biomass(es), ash(es), drying substances, fuels for incineration, carbonaceous or carbon-rich material(s),

d. a system for pounding or powdering the dryed biomass,

e. electronic control system(s) and

f. at least one computer.

### BRIEF DESCRIPTION OF THE DRAWINGS

There are no drawings.

### DETAILED DESCRIPTION OF THE INVENTION

The efficiency of the catalysis by the synthesis of diamonds or diamond-like materials depends on the initial spatial arrangement and distribution of metal atoms in carbon matrix or C-Matrix. Fine dispersion of smaller amounts of metal atoms in the initial carbon matrix before the HPHT reaction can allow more efficient catalysis of the conversion of carbon to the diamond modification and thus more diamonds arise, i.e. the yield of the reaction will be increased.

This fine dispersion cannot be achieved in graphite as well as by simple adding of metal(s). The optimal form of C-matrix is ash or ashes and graphite powder and the optimal form of catalyst(s) for the reaction is a salt or salts. Salts can be dissolved and dispersed in a biomass and/or ash and thus the optimal dispersion can be reached or can be achieved. By using salts preferably added to ash or biomass incinerated to ash as original initial carbon matrix, the quality of the HPHT-resulted diamonds will be improved and the quantity or yield of the resulting synthetic diamonds will be increased (during this HPHT-reaction or process). The biomass is a renewable source of carbon and the continuously cultivated biomass, preferably algal and fungal biomasses, can be isolated and enriched with salts containing catalyst metal(s) and than incinerated to ash(s). These resulting ashes can be directly converted by the HPHT-process to the synthetic diamonds or diamond-like materials. Alternatively, ashes can be additionally enriched with salts and than treated by HPHT.

Any other substance or substances, for example a luminescent or phosphorescent substance(s) can be added to ash or biomass, which will be incinerated or converted to ash. These substances include any form of carbon or carbonaceous material as well as nucleic acids, proteins or other biomolecules, other molecules or their combinations.

Also non-metals and their compounds including non-metal oxides or their combinations can be added to the C-Matrix in order to produce novel diamond-like materials by the HPHT-process.

The preferred non-metals include B, Si, P, S, As, Se, Sb and Te and their compounds and their combinations and the applications of the resulted diamond-like materials include both jewels and technical uses i.e. instruments and devices, including electronic devices and semiconductors and other electronic materials or materials for uses in electronics, as well as for uses as superhard materials.

The metals in carbon matrix and/or metals in salts (dispersed in this carbon matrix) comprise Li,Be,Na,Mg,Al,K,Ca,Sc,Ti,V,Cr,Mn,Fe,Co,Ni,Cu,Zn,Ga,Ge,Rb,Sr,Y,Zr,Nb,Mo,Ru,Rh,Pd,Ag, Cd,In,Sn,Cs,Ba,La,Ce,Pr,Nd,Sm,Eu,Gd,Tb,Dy,Ho,Er,Tm,Yb,Lu,Hf,Ta,W,Re,Os,Ir,Pt,Au,Hg, Tl,Pb and Bi and their combinations. The resulting diamonds and diamond-like materials can be named “salt diamonds” and “metal diamonds”, such as for example lithium diamonds, gold diamonds or golden diamonds, silver diamonds, gold-silver-diamonds, copper diamonds, palladium diamonds and other metal diamonds or combinative metal diamonds.

The halogens in salts are F, Cl, Br and I.

The metal compounds comprise metal oxides, carbides, nitrides, phosphides, sulphides, selenides, silicides, tellurides, arsenides and other compounds and their combinations.

The forms of carbon comprise ashes, graphite graphite powder, glass carbon, amorphous carbon, lonsdaleite, fullerenes, carbon nanotubes, graphene, chaoite, kimberlite, polycrystalline diamond (PCD) and other forms or their combinations.

The carbonaceous material comprises also calcium carbonate and other carbonates and/or their combinations. The biomolecules comprise nucleic acids DNA, RNA, proteins, lignin, chitin, chitosan, cellulose, pectin, trehalose, tocopherol, anthocyans, steroid hormones, haems, haemoglobin, chlorophylls and other molecules associated with photosynthesis, melatonin, melanin, lecithins, kephalins, phosphatides or other molecules or their combinations.

The cells or cell cultures forming biomass comprise alga, e.g. Chlamydomonas spec., Volvox spec. as well as mosses, fishes, Tardigrada, bacteria, fungi, marine organisms, plants and other cells or organisms or their combinations.

The resulting products can be classified by the following formula:

1. CMe or carbon-metal, wherein Me was preferably added to ash as fine powder or a micropowder or nanopowder, such as aluminium or gold or silver nanopowder, and C preferably originates from ash,

2. CMeX, wherein MeX is a salt or at least one salt,

3. CA, wherein A is a non-metal, and C is originated from ash,

4. CE, wherein E is any substance, and C is originated from ash,

5. CMeXA,

6. CMeXE and

7. CMeXAE, wherein CMeXE comprises also CMeXAE.

The synthesis steps include drying and incineration, wherein drying substances comprise calcium chloride, sulphuric acid, silica gel, phosphorus pentoxide, metal oxides, compounds including iron, calcium or their combinations and fuels for incineration comprise carbohydrates comprising kerosene, benzene, oils, coal, lignin, charcoal and coke.

The methods according to the present invention comprise also simplified methods, wherein not all steps will be carried out. For example, a carbonaceous material comprising ash, graphite, graphite powder, glass carbon, amorphous carbon, or their combinations can be enriched with a salt or salts containing at least one catalyst and then treated with HPHT.

The devices according to the present invention for carrying out the methods according to the present invention, including the simplified methods according to the present invention, comprise at least one HPHT apparatus, incineration oven or incinerator with filters, as well as reactors, containers, at least one computer, actuator or actuators and electronic control system(s) and these devices may be simplified or made more complex by adding at least one other element or system.

### EXAMPLES

The following examples show how the present invention can be implemented.

### Example 1

20 L (liters) of algal biomass (Chlamydomonas spec.) are treated or mixed with 4 kg mixtures of salts. There are 4 salts in the same parts: iron-III-chloride, copper chloride, nickel chloride and aluminium chloride. The resulting mixture will be dried with 1 kg calcium chloride and incinerated in the oven, i.e. in the incinerator with filter. The resulting ash is treated with HPHT with the following parameters: pressure=6 GPa, temperature=2. 100° C. and time period=48 hours. After the HPHT-treatment, synthetic diamond products are isolated/separated from the carbon matrix by treatment with diluted sulphuric acid and by using microscope and tweezers.

### Example 2

This Example is similar with the Example 1, wherein the biomass is the 1:1-mixture of alga Chlamydomonas spec. and fungi, yeast Saccharomyces cerevisiae. This 1:1-proportion of cell cultures will be mixed with the salts iron chloride, nickel iodide, copper iodide and titan iodide. The time duration of the HPHT-phase is 48 hours. The incineration occurs with filters.

### Example 3

This Example is similar with the Example 2, wherein the biomass is the algal Chlamydomonas-biomass, and this algal biomass will be mixed with fine gold powder. The HPHT-time period is 24 hours.

### Example 4

This Example is similar with the Examples 2 and 3, wherein algal biomass will be mixed with a gold-containing salt gold chloride.

### Example 5

This Example is similar with the Examples 3 and 4, wherein the algal biomass will be mixed both with the gold powder and gold chloride. The resulting diamonds can be named Golden Diamonds.

### Example 6

This Example is similar with the Example 2, wherein the biomass is the algal biomass and this algal biomass will be mixed with silver iodide. The resulting diamonds can be named Silver Diamonds.

### Example 7

This Example is similar with the Example 6, wherein the algal biomass contains gold and silver, i.e. will be mixed with the fine gold powder silver powder and silver iodide.

### Example 8

This Example is similar with the Example 7, wherein the algal biomass will be mixed with gold powder and silver iodide. The resulting diamonds can be named Gold-Silver-Diamonds.

By these methods can be produced other Salt Diamonds, Combinative Salt Diamonds (CSD), Metal Diamonds including Lithium Diamonds, Lithium-Salt-Diamonds, Lithium Salt-Lithium-Diamonds, Vanadium-Diamonds, Platinum-Diamonds, Copper Diamonds, Gold-Silver-Copper-Diamonds, Gold-Golden Salt-Diamonds (GGSD), Gold-Silver Salt-Diamonds (GSiSaD), Golden Salt-Silver-Diamonds (GSSD), Golden Salt-Silver Salt-Diamonds (GSSSD or G3SD), and other Metal-Combination-Diamonds (MCD), or Combinative Metal Diamonds (CMD), as well as Salt-Metal-Diamonds (SMD) and Combinative Salt-Metal Diamonds (CSMD).

1. A method for production of synthetic diamonds and diamond-like materials comprising the following steps:
a. cultivation or alternative collection, isolation or preparing a biomass, wherein the biomass comprises:
a1.cells or organisms preferably including bacteria, alga, such as green alga Volvox spec. or Chlamydomonas spec., fungi, mosses, lichens, plants, Tardigrada, insects, animal organisms including fishes, marine organisms and other organisms or cells or their combinations or
a2.biomolecules comprising but not limited to the following: DNA, RNA, proteins, peptides, polysaccharides, oligosaccharides, monosaccharides, chitin, chitosan, cellulose, hemicellulose, pectin, hyaloronic acid, lignin, oils, lipids, anthocyans, tocopherol or their combinations, or
a3. combinations of cells and biomolecules listed above in a1 and a2,
b. enriching the biomass with at least one metal or metals, preferably with metal modifiers or catalysts as salts or in form of salts, other metal compounds including metal carbides, phosphides, sulfides, nitrides, tellurides, selenides, borides or other metal compounds, fine metal powders, metal nanopowders or micro- or nanoparticle powders, or mixtures comprising salts and metal powders, mixtures comprising salts and other metal compounds, as well as mixtures comprising salts, other metal compounds and fine metal powders or their combinations,
c. adding to the biomass substances for drying this biomass, wherein these drying substances comprise the following substances, but are not limited to them: calcium chloride, sulphuric acid, silica gel, phoshorus pentoxide, metal oxides, compounds comprising iron, calcium, or their combinations,
d. powdering, powderization or pounding the dryed biomass,
e. adding fuel for incineration wherein the fuel substance includes the following substances, but is not limited to them: kerosene, benzine or gasoline or petrol, coke, coal, charcoal, anthracite or their combinations,
f. adding carbonaceous or carbon-rich material comprising the following substances, but is not limited to them: graphite, ash, glass carbon, amorphous carbon, carbon nanotubes, fullerene or other form of carbon or their combinations,
g. adding at least one non-metal including phosphorus (P), sulphur (S), boron (B), telluric (Te), selenium (Se), silicium (Si), arsenic (As), antimony (Sb) or their compounds or their combinations,
h. incineration of the mass to ash preferably in a oven or incinerator with at least one filter,
i. adding to ash modifiers or catalysts in form of salts or metal halogenides with the formula MeX, wherein Me is metal comprising Li,Be,Na,Mg,Al,K,Ca,Sc,Ti,V,Cr,Mn,Fe,Co,Ni,Cu,Zn,Ge,Ga,Rb,Sr,Y,Zr,Nb,Mo, Ru,Rh,Pd,Ag,Cd,In,Sn,Cs,Ba,La,Ce,Pr,Nd,Sm,Eu,Gd,Tb,Dy,Ho,Er,Tm,Yb,Lu, Hf,Ta,W,Re,Os,Ir,Pt,Au,Hg,Tl,Pb and Bi or their combinations and X is Cl, Br, F or I, or chlorine, bromine, fluorine or iodine, as well as other metal compounds, fine metal powders, or their combinations,
j. adding at least one non-metal or its compound or combination of non-metals, or their compounds,
k. high-pressure-high-temperature (HPHT)-treatment,
l. isolation of synthetic diamonds or diamond like-materials from the resulting matrix material after HPHT-treatment.

2. The method according to claim 1, wherein the HPHT-treatment occurs preferably 10-24 hours, wherein the range may be 24-336 hours, with pressures in a preferable range of 1,5-7 GPa, and temperatures in preferable range of 1.500° C. to 3.000° C.

3. The simplified method according to claim 1, wherein a carbonaceous material including ash, graphite, graphite powder, amorphous carbon, glass carbon, graphene, fullerene, carbon nanotubes or any other form of carbon, or their combinations will be enriched with a salt or salts containing at least one catalyst, this salt or these salts will be dispersed and the resulting carbon-matrix with salt(s) will be treated with HPHT.

4. The simplified method according to claim 1, wherein this method does not comprise the steps g and j.

5. The simplified method according to claim 1, wherein a carbonaceous material comprising ash, graphite, amorphous carbon or their combinations will be enriched with at least one salt containing at least one metal catalyst, as well as will be enriched with other metal compounds or metal-containing compounds, non-metal or non-metals, other non-metal-compounds or non-metal-containing compounds or their combinations and the resulting matrix will be treated with HPHT.

6. The simplified method according to claim 1, comprising only the steps a, b, c, h, i, k and l.

7. The simplified method according to claim 1, wherein this method does not comprise the steps b, e, f, g and j, or does not comprise alternative steps e, f, g, i and j.

8. A device or apparatus for producing synthetic diamonds or diamond like materials and for performing or carrying out the method according to claim 1, comprising:
a. At least one HPHT-apparatus comprising both heater, preferably a graphite heater, and press, preferably hydraulic or oil press, with at least one chamber or capsule for carbon-containing matrix,
b. at least one oven for incineration or at least one incinerator,
c. chambers, reactors, bioreactors, containers for biomass(es), ash(es), drying substances, fuels for incineration, carbonaceous or carbon rich material(s),
d. a system for pounding or powdering the dryed biomass,
e. electronic control system(s) and
f. at least one computer.

9. The device or apparatus according to claim 8, comprising filters, robot or robots, actuators, thermostable walls, dryer and at least one additional element or system.

10. A synthetic diamond or a diamond-like material, wherein
a. it is produced by a method of claim 1 or claims 2-7, or
b. it is produced by or in a device of claim 8 or claim 9, or
c. it contains or comprises a salt or salts and thus is having the general formula CMeX, wherein C is a carbon and MeX is a salt, or at least one salt wherein Me is a metal, preferably a catalyst and X is a halogen, or
d. it has the general formula CMe, wherein C origins from ash, or
e. it has the general formula CA, wherein C is origined from ash and A is a non-metal including B, Si, Se, P, S, As, Te and Sb, or their combinations, or
f. it has the general formula CE, wherein C origins from ash and E is at least one any substance, or
g. it has the general formula CmeXA, wherein MeX is at least one salt and A is a non-metal including B, Si, Se, P, S, As, Te and Sb, or their combinations, or
h. it has the general formula CMeXE, wherein MeX is at least one salt and E is any substance, or
i. it has the heneral formula CMeXAE, wherein MeX is at least one salt, A is at least one non-metal including B,Si,S,Se,P,As,Te and Sb or their combinations and E is at least one any other substance.

11. The synthetic diamond or diamond-like material according to claim 10, comprising at least one metal, a metal compound, including oxide(s), carbides, phosphides, nitrides, a metal-containing compound, a non-metal, preferably Te, B, S, P, As, Sb, Se, Si, a non-metal compound including non-metal oxides, especially oxides of boron, sulphur, selenium, arsenic, silicium, telluric and phosphorus, a non-metal containing compound or their combinations.

12. A synthetic diamond or diamond-like material according to claim 11, comprising luminescent, phosphorenscent and/or any other substance or compound or their combinations.

13. A synthetic diamond or diamond-like material of claim 11, comprising Meta I Diamonds, Salt Diamonds, Non-Metal-Containing Diamonds, including P-Containing Diamonds or PC or P-Diamonds, S-Containing Diamonds or S-Diamonds, B-Containing Diamonds or B-Diamonds, Te-Containing Diamonds or Te-Diamonds, As-Containing Diamonds or As-Diamonds, Se-Containing Diamonds or Se-Diamonds, Combinative Non-Metal Containing Diamonds or Combinative Non-Metal Diamonds, PO-Diamonds or Phosphorus Oxide Diamonds, Salt-Metal-Containing Diamonds or Salt-Metal-Diamonds, Salt-Non-Metal-Containing Diamonds or Salt-Non-Metal-Diamonds, Salt-Metal-Non-Metal-Containing Diamonds or Salt-Metal-Non-Metal-Diamonds, Combinative Metal-Non-Metal-Diamonds, Combinative Salt-Metal-Non-Metal-Diamonds, Combinative Salt-Metal-Diamonds, Combinative Salt-Non-Metal-Diamonds, Combinative Metal Diamonds, Combinative Salt-Diamonds, Metal Diamonds, Lithium-Salt-Diamonds, Lithium Salt-Lithium-Diamonds, Vanadium-Diamonds, Gold Diamonds or Golden Diamonds, Silver Diamonds, Gold-Silver-Diamonds, Platinum Diamonds, Copper Diamonds, Gold-Silver-Copper-Diamonds, Gold-Golden Salt-Diamonds, Gold-Silver Salt-Diamonds, Gold Salt-Silver Diamonds, Gold Salt-Silver Salt-Diamonds, Gold-Gold Salt-Silver-Silver Salt-Diamonds and Gold-Gold Salt-Silver-Silver Salt-Copper-Copper Salt-Diamonds, as well as other Combinative Diamonds.

14. A method according to claim 1, wherein the productivity of HPHT will be increased.
